(19) United States
(12) Patent Application Publication
(10) Pub. No.: US 2025/0149371 A1
(43) Pub. Date: May 8, 2025

(54) ELECTROSTATIC CHUCK UNIT, LAMINATION APPARATUS AND METHOD OF LAMINATION

(71) Applicant: SAMSUNG DISPLAY CO., LTD., YONGIN-SI (KR)

(72) Inventors: TAEYOUNG PARK, Yongin-si (KR); MINSEOK KANG, Yongin-si (KR); MYUNG-HUN OH, Yongin-si (KR); TETSUYA OKAMOTO, Yongin-si (KR); BYUNG MOO KIM, Yongin-si (KR)

(21) Appl. No.: 18/931,528

(22) Filed: Oct. 30, 2024

(30) Foreign Application Priority Data
Nov. 7, 2023 (KR) 10-2023-0153156

(51) Int. Cl. H01L 21/683; B23Q 3/15; B32B 37/00; B32B 37/10

(52) U.S. Cl. CPC H01L 21/6833; B23Q 3/15; B32B 37/0053; B32B 37/10; B32B 2037/1063; B32B 2309/68; B32B 2457/20; H01L 21/6838

(57) ABSTRACT

An electrostatic chuck unit includes a first electrostatic chuck that includes a first plate that includes a surface that is concavely curved in a first direction and a first electrode pattern disposed on the surface of the first plate, and a second electrostatic chuck spaced apart from the first electrostatic chuck in a second direction opposite to the first direction and that includes a second plate that includes a surface adjacent to the first electrostatic chuck and that is convexly curved in the first direction and a second electrode pattern disposed on the surface of the second plate. Each of the first electrode pattern and the second electrode pattern includes an electrode, and a width of the electrode is between 10 mm and 30 mm.

### CROSS-REFERENCE TO RELATED APPLICATION(S)

This application claims priority under 35 U.S.C. § 119 from Korean Patent Application No. 10-2023-0153156, filed on Nov. 7, 2023 in the Korean Intellectual Property Office (KIPO), the contents of which are herein incorporated by reference in their entirety.

### TECHNICAL FIELD

Embodiments are directed to an electrostatic chuck unit. More specifically, embodiments are directed to an electrostatic chuck unit, a lamination apparatus that includes the same, and a method of lamination that uses the same.

### DISCUSSION OF THE RELATED ART

Electrostatic chucks are used to transport or fix objects to be adsorbed, such as substrates, semiconductor wafers, etc., in a manufacturing process of a display device, a semiconductor, etc. An electrostatic chuck generates an electrostatic force by electric potential charged to an electrode inside the chuck and an adsorbed object.

For example, in a lamination process of bonding a display panel and a window using an adhesive layer, the display panel and the window are adsorbed to different electrostatic chucks, and bonding the window to the display panel is performed by pressing the different electrostatic chucks against each other.

### SUMMARY

Embodiments provide an electrostatic chuck unit for manufacturing a curved display device.

Embodiments provide a lamination apparatus that includes the electrostatic chuck unit.

Embodiments provide a method of lamination that uses the electrostatic chuck unit.

An electrostatic chuck unit according to an embodiment of the present disclosure includes a first electrostatic chuck that includes a first plate that includes a surface that is concavely curved in a first direction and a first electrode pattern disposed on the surface of the first plate, and a second electrostatic chuck spaced apart from the first electrostatic chuck in a second direction opposite to the first direction and that includes a second plate that includes a surface adjacent to the first electrostatic chuck and that is convexly curved in the first direction and a second electrode pattern disposed on the surface of the second plate. Each of the first electrode pattern and the second electrode pattern includes an electrode, and a width of the electrode is between about 10 mm and about 30 mm.

In an embodiment, the first electrostatic chuck further includes a first dielectric layer disposed on the first electrode pattern, the second electrostatic chuck further includes a second dielectric layer disposed on the second electrode pattern, and a thickness of each of the first dielectric layer and the second dielectric layer is between about 0.05 mm and about 0.075 mm.

In an embodiment, a distance between the electrode of each of the first electrode pattern and the second electrode pattern is between about 0.5 mm and about 2.0 mm.

In an embodiment, the first electrode pattern includes a first pattern and a second pattern that has a size that differs from a size of the first pattern.

In an embodiment, the first pattern and the second pattern are spaced apart from each other.

In an embodiment, the first plate includes a first sub-plate disposed below the first pattern and a second sub-plate disposed below the second pattern.

In an embodiment, the first sub-plate and the second sub-plate are spaced apart from each other.

In an embodiment, each of the first electrode pattern and the second electrode pattern includes a first area, a second area spaced apart from the first area in a third direction that crosses each of the first direction and the second direction, and a third area located between the first area and the second area. Each of a first width of an electrode in the first area and a second width of an electrode in the second area is less than a third width of an electrode in the third area.

In an embodiment, each of a first distance between electrodes in the first area and a second distance between electrodes in the second area is less than a third distance between electrodes in the third area.

In an embodiment, each of the first electrode pattern and the second electrode pattern includes vacuum holes arranged along a third direction that crosses each of the first direction and the second direction and a fourth direction that crosses each of the first direction, the second direction, and the third direction.

In an embodiment, each of the first electrode pattern and the second electrode pattern includes an alignment mark.

In an embodiment, each of the first electrode pattern and the second electrode pattern includes a first electrode, and a second electrode charged with a polarity that differs from a polarity of the first electrode.

A lamination apparatus according to an embodiment of the present disclosure includes a first chamber, a second chamber adjacent to the first chamber in a first direction, a first electrostatic chuck disposed in the first chamber, and a second electrostatic chuck disposed in the second chamber. The first electrostatic chuck includes a first plate that includes a surface that is concavely curved in a second direction opposite to the first direction and a first electrode pattern disposed on the surface of the first plate. The second electrostatic chuck includes a second plate that includes a surface adjacent to the first electrostatic chuck and that is convexly curved in the second direction and a second electrode pattern disposed on the surface of the second plate. Each of the first electrode pattern and the second electrode pattern includes an electrode, and a width of the electrode is between about 10 mm and about 30 mm.

In an embodiment, the first electrostatic chuck further includes a first dielectric layer disposed on the first electrode pattern, the second electrostatic chuck further includes a second dielectric layer disposed on the second electrode pattern, and a thickness of each of the first dielectric layer and the second dielectric layer is between about 0.05 mm and about 0.075 mm.

In an embodiment, a distance between an electrode of each of the first electrode pattern and the second electrode pattern is between about 0.5 mm and about 2.0 mm.

In an embodiment, the first electrode pattern includes a first pattern and a second pattern that has a size that differs from a size of the first pattern.

In an embodiment, the first pattern and the second pattern are spaced apart from each other.

In an embodiment, the first plate includes a first sub-plate disposed below the first pattern and a second sub-plate disposed below the second pattern.

In an embodiment, the first sub-plate and the second sub-plate are spaced apart from each other.

In an embodiment, each of the first electrode pattern and the second electrode pattern includes a first area, a second area spaced apart from the first area in a third direction that crosses each of the first direction and the second direction, and a third area located between the first area and the second area. Each of a first width of an electrode in the first area and a second width of an electrode in the second area is less than a third width of an electrode in the third area.

In an embodiment, each of a first distance between electrodes in the first area and a second distance between electrodes in the second area is less than a third distance between electrodes in the third area.

In an embodiment, each of the first electrode pattern and the second electrode pattern includes a vacuum hole arranged along a third direction that crosses each of the first direction and the second direction and a fourth direction that crosses each of the first direction, the second direction, and the third direction.

A method of lamination according to an embodiment of the present disclosure includes molding a shape of a display panel, adsorbing the display panel to a surface of a first electrostatic chuck, adsorbing a window to a surface of a second electrostatic chuck adjacent to the first electrostatic chuck, wherein the second electrostatic chuck is spaced apart from the first electrostatic chuck in a first direction, and bonding the display panel and the window by using the first electrostatic chuck and the second electrostatic chuck.

In an embodiment, the molding of the shape of the display panel includes molding the display panel to be curved in a second direction opposite to the first direction.

In an embodiment, the molding of the shape of the display panel includes molding the display panel by using a stage and a bending jig spaced from the stage in the first direction and that is curved in a second direction opposite to the first direction.

In an embodiment, the stage includes a first side stage, a center stage spaced apart from the first side stage in a third direction that crosses each of the first direction and the second direction, a second side stage spaced apart from the center stage in the third direction, a first roller disposed between the first side stage and the center stage, and a second roller disposed between the center stage and the second side stage.

In an embodiment, the molding of the shape of the display panel includes placing the display panel on the stage, moving the first side stage, the second side stage, and the bending jig in the second direction to contact the bending jig and the display panel, moving the first roller in a fourth direction opposite to the third direction and moving the second roller in the third direction, and moving the bending jig in the second direction to mold the display panel.

In an embodiment, the molding of the shape of the display panel includes placing the display panel on the stage, moving the first side stage, the second side stage, and the bending jig in the second direction to contact the bending jig and the display panel, moving the center stage in the second direction, and moving the first roller in a fourth direction opposite to the third direction, moving the second roller in the third direction, and moving the bending jig in the second direction to mold the display panel.

In an embodiment, the molding of the shape of the display panel includes placing the display panel on the stage, moving the bending jig in the second direction to contact the bending jig and the display panel, and rolling the bending jig in the third direction and in a fourth direction opposite to the third direction to mold the display panel.

In an embodiment, the surface of the first electrostatic chuck is concavely curved in a second direction opposite to the first direction, and the surface of the second electrostatic chuck is convexly curved in the second direction.

In a lamination apparatus according to embodiments of the present disclosure, the lamination apparatus includes an electrostatic chuck unit that includes a first electrostatic chuck and a second electrostatic chuck that have surfaces facing each other and that are curved in a same direction. Accordingly, a lamination process of bonding a curved display panel and a curved window can be performed, and a curved display device can be manufactured.

In addition, the first electrostatic chuck includes a first structure and at least one second structure that adsorb different objects. Accordingly, a lamination process of bonding a window and a plurality of display panels can be performed, and a curved display device that includes a plurality of display panels can be manufactured.

### BRIEF DESCRIPTION OF THE DRAWINGS

FIG. 1 is a cross-sectional view of a lamination apparatus according to an embodiment of the present disclosure.

FIG. 2 is a perspective view of an electrostatic chuck unit in a lamination apparatus of FIG. 1.

FIG. 3 is a plan view of an electrode pattern in an electrostatic chuck unit of FIG. 2.

FIG. 4 is a cross-sectional view taken along line I-I′ of FIG. 2.

FIG. 5 is a plan view of an electrode pattern in an electrostatic chuck unit of FIG. 2.

FIG. 6 is a plan view of an electrode pattern in an electrostatic chuck unit of FIG. 2.

FIGS. 7, 8, 9, 10, 11, 12, and 13 illustrate a method of lamination according to an embodiment of the present disclosure.

FIGS. 14, 15, 16, and 17 illustrate a method of lamination according to an embodiment of the present disclosure.

FIGS. 18, 19, 20, and 21 illustrate a method of lamination according to an embodiment of the present disclosure.

FIG. 22 is a cross-sectional view of a lamination apparatus according to an embodiment of the present disclosure.

FIG. 23 is a perspective view of an electrostatic chuck unit in a lamination apparatus of FIG. 22.

FIG. 24 is a cross-sectional view of a lamination apparatus according to an embodiment of the present disclosure.

FIG. 25 is a perspective view of an electrostatic chuck unit in a lamination apparatus of FIG. 24.

### DETAILED DESCRIPTION

Hereinafter, embodiments of the present disclosure will be described in more detail with reference to the accompanying drawings. The same reference numerals may be used for the same components in the drawings, and repeated descriptions of the same components may be omitted.

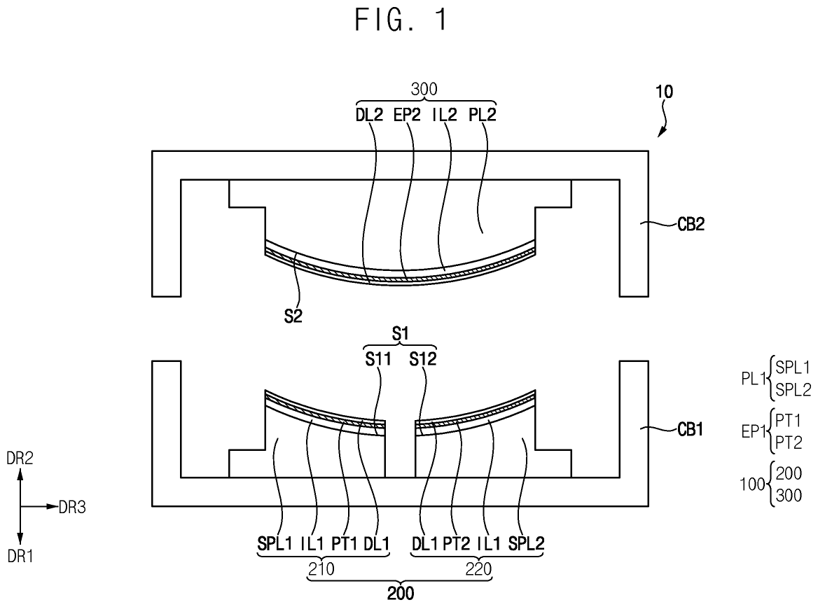

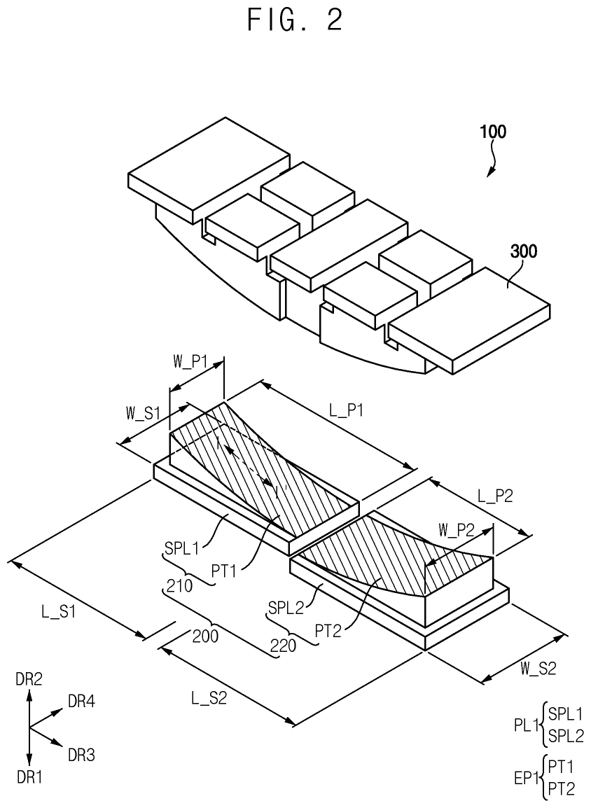

FIG. 1 is a cross-sectional view of a lamination apparatus according to an embodiment of the present disclosure. FIG. 2 is a perspective view of an electrostatic chuck unit in a lamination apparatus of FIG. 1.

Referring to FIGS. 1 and 2, in an embodiment, a lamination apparatus 10 includes a first chamber CB1, a second chamber CB2, and an electrostatic chuck unit 100. The electrostatic chuck unit 100 includes a first electrostatic chuck 200 and a second electrostatic chuck 300.

The lamination apparatus 10 may be used in a manufacturing process of a display device. For example, the lamination apparatus 10 can be used in a lamination process in the manufacturing process of a display device. The lamination apparatus 10 bonds a first object and a second object adsorbed on the first electrostatic chuck 200 and a third object adsorbed on the second electrostatic chuck 300. For example, each of the first object and the second object are a display panel of a display device, and the third object is a window that protects the display panel.

The first chamber CB1 is adjacent to the second chamber CB2 in a first direction DR1. Each of the first chamber CB1 and the second chamber CB2 provides a space for performing the lamination process. An inside of each of the first chamber CB1 and the second chamber CB2 is maintained in a vacuum state, but embodiments of the present disclosure are not necessarily limited thereto.

The first electrostatic chuck 200 is disposed in the first chamber CB1, and the second electrostatic chuck 300 is disposed in the second chamber CB2. For example, the second electrostatic chuck 300 is spaced apart from the first electrostatic chuck 200 in a second direction DR2 opposite to the first direction DR1.

The first electrostatic chuck 200 includes a first plate PL1, a first insulating layer IL1, a first electrode pattern EP1, and a first dielectric layer DL1. The first plate PL1 includes a first sub-plate SPL1 and a second sub-plate SPL2, and the first electrode pattern EP1 includes a first pattern PT1 and a second pattern PT2.

For example, the first electrostatic chuck 200 includes a first structure 210 that includes the first sub-plate SPL1, the first insulating layer IL1, the first pattern PT1, and the first dielectric layer DL1, and a second structure 220 that includes the second sub-plate SPL2, the first insulating layer IL1, the second pattern PT2, and the first dielectric layer DL1.

Each of the first structure 210 and the second structure 220 can adsorb an object. For example, the first structure 210 can adsorb a first object, and the second structure 220 can adsorb a second object. In an embodiment, the first object and the second object are different sized display panels. However, embodiments of the present disclosure are not necessarily limited thereto, and in an embodiment, the first object and the second object are same sized display panels.

In an embodiment, the first structure 210 and the second structure 220 are spaced apart from each other. For example, the second structure 220 is spaced apart from the first structure 210 in a third direction DR3 that crosses each of the first direction DR1 and the second direction DR2. For example, the third direction DR3 is perpendicular to each of the first direction DR1 and the second direction DR2. However, embodiments of the present disclosure are not necessarily limited thereto, and in an embodiment, the first structure 210 and the second structure 220 are in contact with each other without being spaced apart from each other.

The first plate PL1 is supported by the first chamber CB1. In an embodiment, a surface S1 of the first plate PL1 adjacent to the second electrostatic chuck 300 is concavely curved in the first direction DR1. The surface S1 of the first plate PL1 has a predetermined curvature.

The first plate PL1 includes the first sub-plate SPL1 and the second sub-plate SPL2. In an embodiment, the first sub-plate SPL1 and the second sub-plate SPL2 are spaced apart from each other. In an embodiment, the first sub-plate SPL1 and the second sub-plate SPL2 are in contact with each other.

In an embodiment, a size of the first sub-plate SPL1 differs from a size of the second sub-plate SPL2.

For example, a first length L_S1 of the first sub-plate SPL1 differs from a second length L_S2 of the second sub-plate SPL2. The first length L_S1 and the second length L_S2 are respective lengths of the first sub-plate SPL1 and the second sub-plate SPL2 in the third direction DR3. For example, the first length L_S1 is less than the second length L_S2, but the present disclosure is not limited thereto.

For example, a first width W_S1 of the first sub-plate SPL1 differs from a second width W_S2 of the second sub-plate. The first width W_S1 and the second width W_S2 are respective lengths of the first sub-plate SPL1 and the second sub-plate SPL2 in a fourth direction DR4 that crosses the first, second, and third directions DR1, DR2, and DR3. For example, the first width W_S1 is less than the second width W_S2, but embodiments of the present disclosure are not necessarily limited thereto.

In an embodiment, the size of the first sub-plate SPL1 is the same as the size of the second sub-plate SPL2. For example, the first length L_S1 is equal to the second length L_S2, and the first width W_S1 is equal to the second width W_S2.

The surface S1 of the first plate PL1 includes a first surface S11 of the first sub-plate SPL1 and a second surface S12 of the second sub-plate SPL2. Each of the first surface S11 and the second surface S12 has a predetermined curvature. In an embodiment, a curvature of the first surface S11 is the same as a curvature of the second surface S12. In an embodiment, the curvature of the first surface S11 differs from the curvature of the second surface S12.

The first insulating layer IL1 is disposed on the surface S1 of the first plate PL1. A portion of the first insulating layer IL1 is disposed on the first sub-plate SPL1, and another portion of the first insulating layer IL1 is disposed on the second sub-plate SPL2. The first insulating layer IL1 is disposed along a profile of the surface S1 of the first plate PL1. For example, the first insulating layer IL1 is concavely curved in the first direction DR1.

The first insulating layer IL1 protects the first plate PL1 and the first electrode pattern EP1. The first insulating layer IL1 prevents damage to the first plate PL1 and the first electrode pattern EP1 that can occur due to pressure applied in the lamination process. The first insulating layer IL1 may be referred to as a cushion layer, a protective layer, etc. The first insulating layer IL1 may include polyimide, but embodiments of the present disclosure are not necessarily limited thereto.

The first electrode pattern EP1 is disposed on the first insulating layer IL1. The first electrode pattern EP1 is disposed along a profile of the first insulating layer IL1. For example, the first electrode pattern EP1 is concavely curved in the first direction DR1. The first electrode pattern EP1 includes a plurality of electrodes. The first electrode pattern EP1 includes a metal. For example, the first electrode pattern EP1 includes copper (Cu), but embodiments of the present disclosure are not necessarily limited thereto.

The first electrode pattern EP1 includes the first pattern PT1 and the second pattern PT2. The first pattern PT1 is disposed on the first sub-plate SPL1, and the second pattern PT2 is disposed on the second sub-plate SPL2. In an embodiment, the first pattern PT1 and the second pattern PT2 are spaced apart from each other. In an embodiment, the first pattern PT1 and the second pattern PT2 are in contact with each other.

In an embodiment, a size of the first pattern PT1 differs from a size of the second pattern PT2.

For example, a first length L_P1 of the first pattern PT1 differs from a second length L_P2 of the second pattern PT2. The first length L_P1 and the second length L_P2 are respective lengths of the first pattern PT1 and the second pattern PT2 in the third direction DR3. For example, the first length L_P1 is less than the second length L_P2, but embodiments of the present disclosure are not necessarily limited thereto.

For example, a first width W_P1 of the first pattern PT1 differs from a second width W_P2 of the second pattern PT2. The first width W_P1 and the second width W_P2 are respective lengths of the first pattern PT1 and the second pattern PT2 in the fourth direction DR4. For example, the first width W_P1 is less than the second width W_P2, but embodiments of the present disclosure are not necessarily limited thereto.

In an embodiment, the size of the first pattern PT1 is the same as the size of the second pattern PT2. For example, the first length L_P1 is equal to the second length L_P2, and the first width W_P1 is equal to the second width W_P2.

When a voltage is applied to the first pattern PT1, a potential difference occurs between the first pattern PT1 and a first object. The potential difference generates an electrostatic force between the first pattern PT1 and the first object, and accordingly, the first object is adsorbed to the first structure 210. However, when the voltage is no longer applied to the first pattern PT1, the electrostatic force generated between the first pattern PT1 and the first object disappears, and accordingly, the first object can separate from the first structure 210.

Likewise, when a voltage is applied to the second pattern PT2, a potential difference occurs between the second pattern PT2 and a second object. The potential difference generates an electrostatic force between the second pattern PT2 and the second object, and accordingly, the second object is adsorbed to the second structure 220. However, when the voltage is no longer applied to the second pattern PT2, the electrostatic force generated between the second pattern PT2 and the second object disappears, and accordingly, the second object can separate from the second structure 220.

The first dielectric layer DL1 is disposed on the first electrode pattern EP1. A portion of the first dielectric layer DL1 is disposed on the first pattern PT1, and another portion of the first dielectric layer DL1 is disposed on the second pattern PT2. The first dielectric layer DL1 is disposed along a profile of the first electrode pattern EP1. For example, the first dielectric layer DL1 is concavely curved in the first direction DR1. Each of the first object and the second object is adsorbed on the first dielectric layer DL1.

The first dielectric layer DL1 insulates the first electrode pattern EP1 from the first and second objects. For example, the first dielectric layer DL1 insulates the first pattern PT1 from the first object, and insulates the second pattern PT2 from the second object. The first dielectric layer DL1 may have a single layer structure or a multilayer structure. For example, the first dielectric layer DL1 includes a first layer and a second layer disposed on the first layer. For example, the first layer includes epoxy, and the second layer includes polyimide, but embodiments of the present disclosure are not necessarily limited thereto.

Accordingly, the first electrostatic chuck 200 includes the first plate PL1, the first insulating layer IL1, the first electrode pattern EP1, and the first dielectric layer DL1, and is supported by the first chamber CB1. For example, the first structure 210 includes the first sub-plate SPL1, the first insulating layer IL1, the first pattern PT1, and the first dielectric layer DL1, and the second structure 220 includes the first sub-plate SPL2, the first insulating layer IL1, the second pattern PT2, and the first dielectric layer DL1, and the first structure 210 and the second structure 220 are supported by the first chamber CB1.

The second electrostatic chuck 300 includes a second plate PL2, a second insulating layer IL2, a second electrode pattern EP2, and a second dielectric layer DL2.

The second plate PL2 is supported by the second chamber CB2. In an embodiment, a surface S2 of the second plate PL2 adjacent to the first electrostatic chuck 200 is convexly curved in the first direction DR1. The surface S2 of the second plate PL2 has a predetermined curvature.

The second insulating layer IL2 is disposed on the surface S2 of the second plate PL2. The second insulating layer IL2 is disposed along a profile of the surface S2 of the second plate PL2. For example, the second insulating layer IL2 is convexly curved in the first direction DR1.

The second insulating layer IL2 protects the second plate PL2 and the second electrode pattern EP2. The second insulating layer IL2 prevents damage to the second plate PL2 and the second electrode pattern EP2 that can occur due to pressure applied in the lamination process. The second insulating layer IL2 may be referred to as a cushion layer, a protective layer, etc. The second insulating layer IL2 may include polyimide, but embodiments of the present disclosure are not necessarily limited thereto.

The second electrode pattern EP2 is disposed on the second insulating layer IL2. The second electrode pattern EP2 is disposed along a profile of the second insulating layer IL2. For example, the second electrode pattern EP2 is convexly curved in the first direction DR1. The second electrode pattern EP2 includes a plurality of electrodes. The second electrode pattern EP2 includes a metal. For example, the second electrode pattern EP2 includes copper, but embodiments of the present disclosure are not necessarily limited thereto.

When a voltage is applied to the second electrode pattern EP2, a potential difference occurs between the second electrode pattern EP2 and a third object. The potential difference generates an electrostatic force between the second electrode pattern EP2 and the third object, and accordingly, the third object is adsorbed to the second electrostatic chuck 300. However, when the voltage is no longer applied to the second electrode pattern EP2, the electrostatic force generated between the second electrode pattern EP2 and the third object disappears, and accordingly, the third object can separate from the second electrostatic chuck 300.

The second dielectric layer DL2 is disposed on the second electrode pattern EP2. The second dielectric layer DL2 is disposed along a profile of the second electrode pattern EP2. For example, the second dielectric layer DL2 is convexly curved in the first direction DR1. The third object is adsorbed on the second dielectric layer DL2.

The second dielectric layer DL2 insulates the second electrode pattern EP2 from the third object. The second dielectric layer DL2 may have a single layer structure or a multilayer structure. For example, the second dielectric layer DL2 includes a first layer and a second layer disposed on the first layer. For example, the first layer includes epoxy, and the second layer includes polyimide, but embodiments of the present disclosure are not necessarily limited thereto.

Accordingly, the second electrostatic chuck 300 includes the second plate PL2, the second insulating layer IL2, the second electrode pattern EP2, and the second dielectric layer DL2, and is supported by the second chamber CB2.

FIGS. 1 and 2 show that the first electrostatic chuck 200 includes two structures, such as the first and second structures 210 and 220, and adsorbs two objects, but embodiments of the present disclosure are not necessarily limited thereto. In other embodiments, the first electrostatic chuck 200 includes three or more structures, or adsorbs three or more objects.

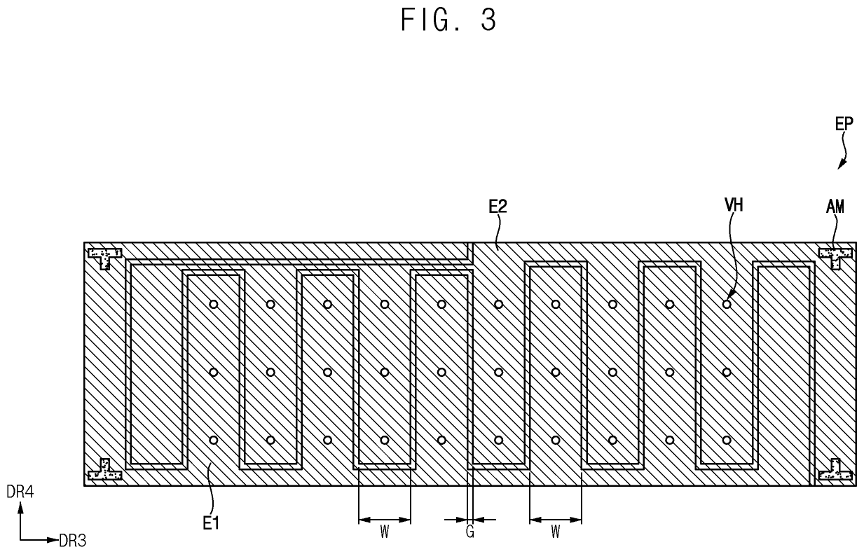

FIG. 3 is a plan view of an electrode pattern in an electrostatic chuck unit of FIG. 2.

For example, an electrode pattern EP described with reference to FIG. 3 corresponds to the first electrode pattern EP1 and the second electrode pattern EP2 described with reference to FIGS. 1 and 2. For example, the electrode pattern EP corresponds to any one of the first pattern PT1, the second pattern PT2, and the second electrode pattern EP2.

Referring to FIGS. 2 and 3, in an embodiment, the electrode pattern EP includes a first electrode E1 and a second electrode E2. The first electrode E1 and the second electrode E2 are alternately disposed along the third direction DR3.

In an embodiment, the second electrode E2 is charged with a different polarity from the first electrode E1. For example, the first electrode E1 is a positive electrode, and the second electrode E2 is a negative electrode. For example, the first electrode E1 is applied with a positive voltage, and the second electrode E2 is applied with a negative voltage. Accordingly, a charge opposite to that of the electrode pattern EP, such as the first electrode pattern EP1, is induced in the first object and the second object adsorbed on the first electrostatic chuck 200, and a charge opposite to that of the electrode pattern EP, such as the second electrode pattern EP2, is induced in the third object adsorbed on the second electrostatic chuck 300.

For example, a portion of each of the first, second, and third objects disposed on the first electrode E1 has a negative charge, and another portion of each of the first, second, and third objects disposed on the second electrode E2 has a positive charge. Accordingly, the electrode pattern EP provides an electrostatic force that adsorbs and fixes the first, second, and third objects. For example, the first electrostatic chuck 200 adsorbs and fixes the first object and the second object by the electrostatic force provided by the electrode pattern EP, such as the first electrode pattern EP1, and the second electrostatic chuck 300 adsorbs and fixes the third object by the electrostatic force provided by the electrode pattern EP, such as the second electrode pattern EP2.

For example, the first electrode E1 is a negative electrode, and the second electrode E2 is a positive electrode. For example, the first electrode E1 is applied with a negative voltage, and the second electrode E2 is applied with a positive voltage. Accordingly, a portion of each of the first, second, and third objects disposed on the first electrode E1 has a positive charge, and another portion of each of the first, second, and third objects disposed on the second electrode E2 has a negative charge. Accordingly, the first electrostatic chuck 200 adsorbs and fixes the first object and the second object by the electrostatic force provided by the electrode pattern EP, such as the first electrode pattern EP1, and the second electrostatic chuck 300 adsorbs and fixes the third object by the electrostatic force provided by the electrode pattern EP, such as the second electrode pattern EP2.

Each of the first electrode E1 and the second electrode E2 includes a metal. For example, each of the first electrode E1 and the second electrode E2 includes copper, but embodiments of the present disclosure are not necessarily limited thereto.

The first electrode E1 and the second electrode E2 have the same width W. The width W is a length of each of the first electrode E1 and the second electrode E2 in the third direction DR3. In an embodiment, the width W of each of the first electrode E1 and the second electrode E2 may be about 10 mm to about 30 mm. For example, the width W of each of the first electrode E1 and the second electrode E2 is about 10 mm, but embodiments of the present disclosure are not necessarily limited thereto, and the width W can variously change in other embodiments. Since the width W of each of the first electrode E1 and the second electrode E2 is about 10 mm to about 30 mm, the electrode pattern EP can generate a stable electrostatic force to adsorb an object.

The first electrode E1 and the second electrode E2 are spaced apart from each other by a predetermined distance. In an embodiment, a distance G between the first electrode E1 and the second electrode E2 may be about 0.5 mm to about 2.0 mm. For example, the distance G is about 1.0 mm, but embodiments of the present disclosure are not necessarily limited thereto, and the distance G can variously change in other embodiments.

The electrode pattern EP further includes an alignment mark AM. For example, the alignment mark AM is positioned at a corner of the electrode pattern EP, but embodiments of the present disclosure are not necessarily limited thereto. Whether the first electrostatic chuck 200 and the second electrostatic chuck 300 are aligned can be easily determined by the alignment mark AM. For example, a camera can photograph the alignment mark AM, and accordingly, confirm whether the first electrostatic chuck 200 and the second electrostatic chuck 300 are aligned.

In a lamination process, when the first electrostatic chuck 200 or the second electrostatic chuck 300 are replaced, depending on an object, the replacement can be quickly performed by using the alignment mark AM.

FIG. 3 shows that the electrode pattern EP includes four alignment marks AM, but embodiments of the present disclosure are not necessarily limited thereto. For example, the electrode pattern EP may include three or less or five or more alignment marks AM.

The electrode pattern EP includes a vacuum hole VH. The vacuum hole VH penetrates the electrode pattern EP. For example, the vacuum holes VH are arranged along the third direction DR3 and the fourth direction DR4. A vacuum suction force is generated through the vacuum hole VH. For example, a vacuum suction force generated by a vacuum pump coupled to each of the first electrostatic chuck 200 and the second electrostatic chuck 300 is transmitted to the vacuum hole VH.

The first electrostatic chuck 200 and the second electrostatic chuck 300 can adsorb and fix the first, second, and third objects, respectively, through the vacuum hole VH. For example, the first electrostatic chuck 200 adsorbs the first object and the second object by a vacuum suction force through the vacuum hole VH, and then, adsorbs the first object and the second object by an electrostatic force through the first electrode pattern EP1. Likewise, the second electrostatic chuck 300 adsorbs the third object by a vacuum suction force through the vacuum hole VH, and then, adsorbs the third object by an electrostatic force through the second electrode pattern EP2.

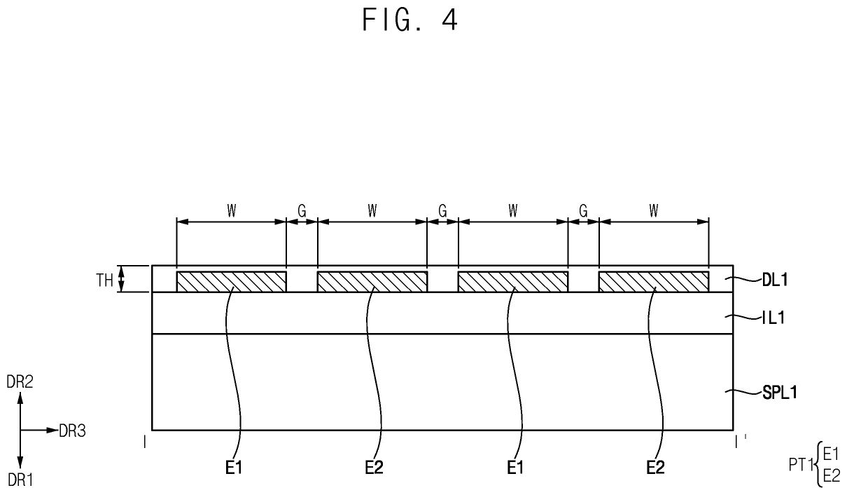

FIG. 4 is a cross-sectional view taken along line I-I′ of FIG. 2. For example, FIG. 4 is a cross-sectional view of a portion of the first structure 210 in the first electrostatic chuck 200.

Referring to FIGS. 1, 2, 3, and 4, in an embodiment, the first structure 210 includes the first sub-plate SPL1, the first insulating layer IL1, the first pattern PT1, and the first dielectric layer DL1.

The first insulating layer IL1 and the first pattern PT1 are sequentially disposed on the first sub-plate SPL1. The first pattern PT1 includes the first electrode E1 and the second electrode E2, which are charged with different polarities. The first electrode E1 and the second electrode E2 are alternately arranged along the third direction DR3. In an embodiment, the width W of each of the first electrode E1 and the second electrode E2 is between about 10 mm and about 30 mm, and the distance G between the first electrode E1 and the second electrode E2 is between about 0.5 mm and about 2.0 mm, but embodiments of the present disclosure are not necessarily limited thereto.

The first dielectric layer DL1 is disposed on the first pattern PT1, and covers the first pattern PT1. The first dielectric layer DL1 is disposed between the first electrode E1 and the second electrode E2. The first dielectric layer DL1 insulates the first electrode E1 from the second electrode E2.

In an embodiment, a thickness TH of the first dielectric layer DL1 is between about 0.05 mm and about 0.075 mm. The thickness TH is a length of the first dielectric layer DL1 in the second direction DR2. For example, when the first dielectric layer DL1 has a multilayer structure that includes a first layer and a second layer, a sum of a thickness of the first layer and a thickness of the second layer is between about 0.05 mm and about 0.075 mm. For example, the thickness TH is about 0.05 mm, but embodiments of the present disclosure are not necessarily limited thereto, and the thickness TH can variously change in other embodiments.

FIG. 4 is a cross-sectional view of the first structure 210 in the first electrostatic chuck 200, but FIG. 4 also corresponds to a cross-sectional view of each of the second structure 220 in the first electrostatic chuck 200 and the second electrostatic chuck 300.

For example, the first sub-plate SPL1 of FIG. 4 corresponds to the second sub-plate SPL2 of the second structure 220 and the second plate PL2 of the second electrostatic chuck 300. The first insulating layer IL1 of FIG. 4 corresponds to the first insulating layer IL1 of the second structure 220 and the second insulating layer IL2 of the second electrostatic chuck 300. The first pattern PT1 of FIG. 4 corresponds to the second pattern PT2 of the second structure 220 and the second electrode pattern EP2 of the second electrostatic chuck 300. The first dielectric layer DL1 of FIG. 4 corresponds to the first dielectric layer DL1 of the second structure 220 and the second dielectric layer DL2 of the second electrostatic chuck 300.

Accordingly, in an embodiment, a thickness of the first dielectric layer DL1 of the second structure 220 and a thickness of the second dielectric layer DL2 of the second electrostatic chuck 300 are between about 0.05 mm and about 0.075 mm, but embodiments of the present disclosure are not necessarily limited thereto.

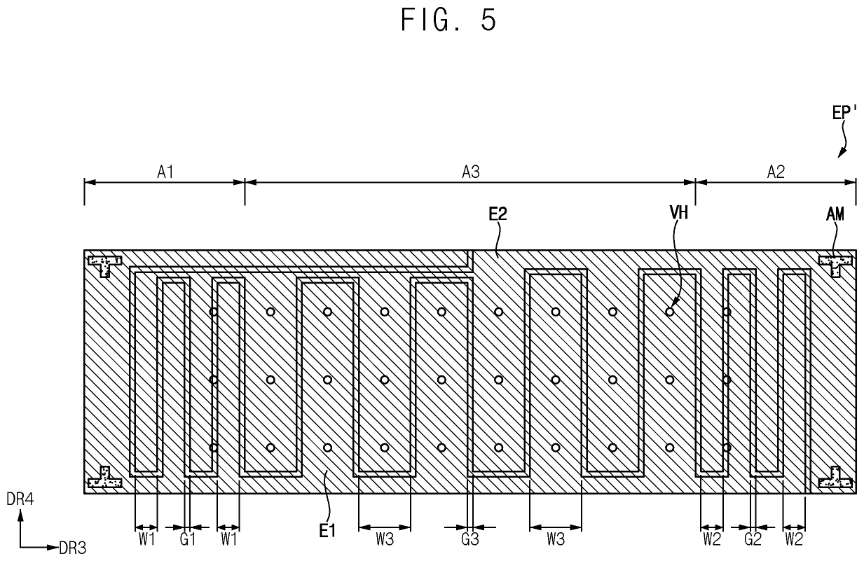

FIG. 5 is a plan view of an electrode pattern in an electrostatic chuck unit of FIG. 2.

For example, an electrode pattern EP′ described with reference to FIG. 5 corresponds to the first electrode pattern EP1 and the second electrode pattern EP2 described with reference to FIGS. 1 and 2. For example, the electrode pattern EP′ corresponds to any one of the first pattern PT1, the second pattern PT2, and the second electrode pattern EP2.

Hereinafter, descriptions of the electrode pattern EP′ that repeat a description provided with reference to FIG. 3 may be omitted or summarized.

Referring to FIGS. 2 and 5, in an embodiment, the electrode pattern EP′ includes the first electrode E1 and the second electrode E2, which are alternately disposed along the third direction DR3. The first electrode E1 and the second electrode E2 are charged with different polarities.

The electrode pattern EP′ includes a first area A1 and a second area A2 spaced apart from the first area A1 in the third direction DR3, and a third area A3 located between the first area A1 and the second area A2. For example, the first area A1 and the second area A2 are side areas of the electrode pattern EP′, and the third area A3 is a center area of the electrode pattern EP′.

In each of the first, second, and third areas A1, A2, and A3, the first electrode E1 and the second electrode E2 have the same width. For example, each of the first electrode E1 and the second electrode E2 has a first width W1 in the first area A1, each of the first electrode E1 and the second electrode E2 has a second width W2 in the second area A2, and each of the first electrode E1 and the second electrode E2 has a third width W3 in the third area A3.

In an embodiment, each of the first width W1 and the second width W2 is less than the third width W3. For example, each of the first width W1 and the second width W2 is about 5 mm, and the third width W3 is about 10 mm, but embodiments of the present disclosure are not necessarily limited thereto.

In each of the first, second, and third areas A1, A2, and A3, the first electrode E1 and the second electrode E2 are spaced apart from each other in the third direction DR3 by a predetermined distance. For example, the first electrode E1 and the second electrode E2 are spaced apart from each other by a first distance G1 in the first area A1, the first electrode E1 and the second electrode E2 are spaced apart from each other by a second distance G2 in the second area A2, and the first electrode E1 and the second electrode E2 are spaced apart from each other by a third distance G3 in the third area A3.

In an embodiment, each of the first distance G1 and the second distance G2 is less than the third distance G3. For example, each of the first distance G1 and the second distance G2 is about 0.5 mm, and the third distance G3 is about 1.0 mm, but embodiments of the present disclosure are not necessarily limited thereto.

When the electrode pattern EP′ has a predetermined curvature, an adsorption force of the side areas of the electrode pattern EP′ is relatively weaker than an adsorption force of the center area of the electrode pattern EP′. For example, an adsorption force of the electrode pattern EP′ in the first area A1 and the second area A2 is relatively weaker than an adsorption force of the electrode pattern EP′ in the third area A3.

Accordingly, the adsorption force of the electrode pattern EP′ in the first area A1 and the second area A2 is strengthened by forming each of the first width W1 in the first area A1 and the second width W2 in the second area A2 to be less than the third width W3 in the third area A3. In addition, the adsorption force of the electrode pattern EP′ in the first area A1 and the second area A2 is strengthened by forming each of the first distance G1 in the first area A1 and the second distance G2 in the second area A2 to be less than the third distance G3 in the third area A3. For example, the electrode pattern EP′ generates a stable electrostatic force that adsorbs an object in the first, second, and third areas A1, A2, and A3.

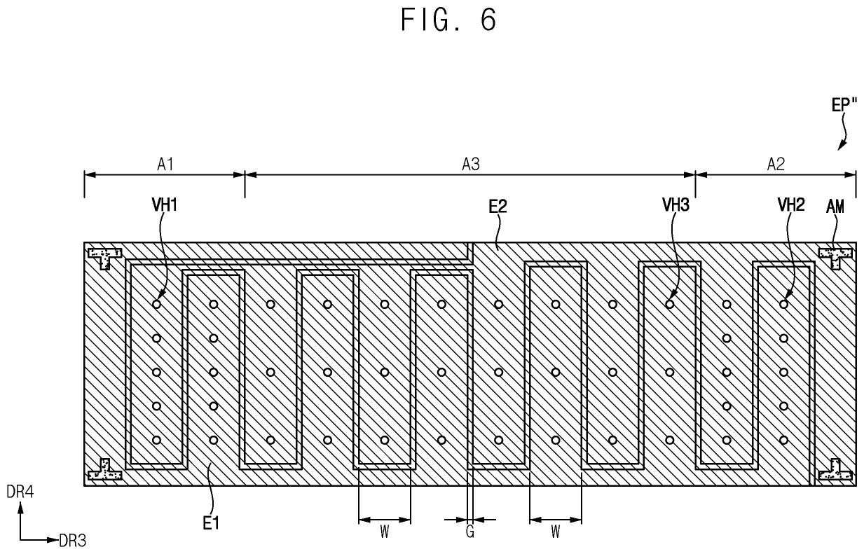

FIG. 6 is a plan view of an electrode pattern in an electrostatic chuck unit of FIG. 2.

For example, an electrode pattern EP″ described with reference to FIG. 6 corresponds to the first electrode pattern EP1 and the second electrode pattern EP2 described with reference to FIGS. 1 and 2. For example, the electrode pattern EP″ corresponds to the first pattern PT1, the second pattern PT2, and the second electrode pattern EP2.

Hereinafter, descriptions of the electrode pattern EP″ that repeat a description provided with reference to FIG. 3 and a description of the electrode pattern EP′ provided with reference to FIG. 5 may be omitted or summarized.

Referring to FIGS. 2 and 6, in an embodiment, the electrode pattern EP″ includes the first electrode E1 and the second electrode E2, which are alternately disposed along the third direction DR3. The first electrode E1 and the second electrode E2 are charged with different polarities.

The electrode pattern EP″ includes the first area A1 and the second area A2 spaced apart from the first area A1 in the third direction DR3, and the third area A3 located between the first area A1 and the second area A2.

The electrode pattern EP″ includes a vacuum hole. For example, the electrode pattern EP″ includes a first vacuum hole VH1 in the first area A1, a second vacuum hole VH2 in the second area A2, and a third vacuum hole VH3 in the third area A3. For example, the first, second, and third vacuum holes VH1, VH2, and VH3 are arranged along the third direction DR3 and the fourth direction DR4.

In an embodiment, a number of the first vacuum holes VH1 per area and a number of the second vacuum holes VH2 per area are greater than a number of the third vacuum holes VH3 per area. For example, a number of the first vacuum holes VH1 arranged in one row along the fourth direction DR4 in the first area A1 and a number of the second vacuum holes VH2 arranged in one row along the fourth direction DR4 in the second area A2 are greater than a number of the third vacuum holes VH3 arranged in one row along the fourth direction DR4 in the third area A3, but embodiments of the present disclosure are not necessarily limited thereto.

Accordingly, an adsorption force of the electrode pattern EP″ in the first area A1 and the second area A2 is strengthened by forming a number of the first vacuum holes VH1 per area in the first area A1 and a number of the second vacuum holes VH2 per area in the second area A2 that are greater than the number of the third vacuum holes VH3 per area in the third area A3. For example, the electrode pattern EP″ generates a stable electrostatic force that adsorbs an object in the first, second, and third areas A1, A2, and A3.

The lamination apparatus 10 according to an embodiment of the present disclosure includes the electrostatic chuck unit 100 that includes the first electrostatic chuck 200 that includes the surface S1 concavely curved in the first direction DR1, and the second electrostatic chuck 300 that includes the surface S2 convexly curved in the first direction DR1. Accordingly, a lamination process of adsorbing a curved display panel and a curved window can be performed, and a curved display device can be manufactured.

In addition, the first electrostatic chuck 200 includes the first structure 210 and at least one second structure 220 that adsorb different objects. Accordingly, a lamination process of adsorbing a window and a plurality of display panels can be performed, and a curved display device that includes a plurality of display panels can be manufactured.

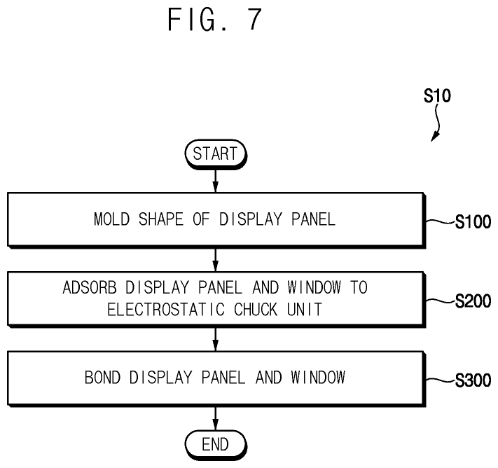

FIGS. 7, 8, 9, 10, 11, 12, and 13 illustrate a lamination method according to an embodiment of the present disclosure.

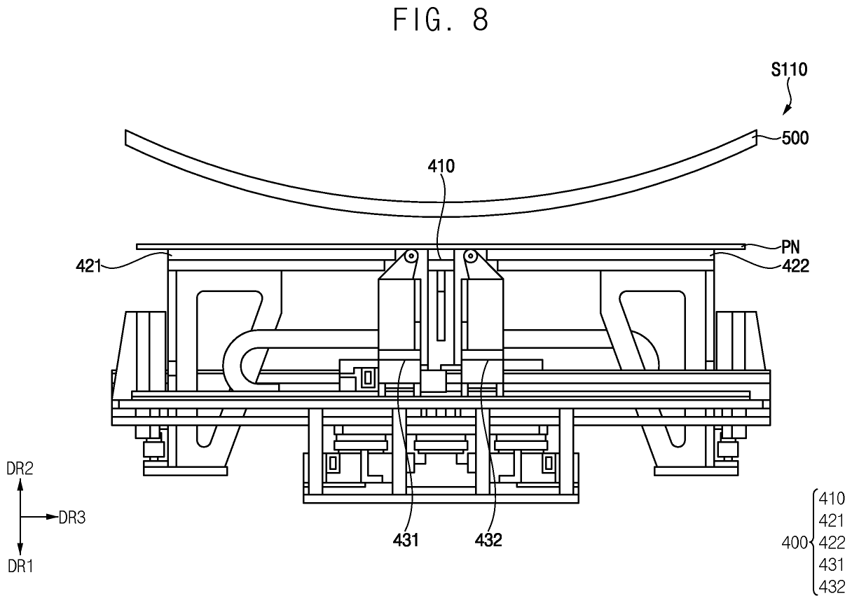

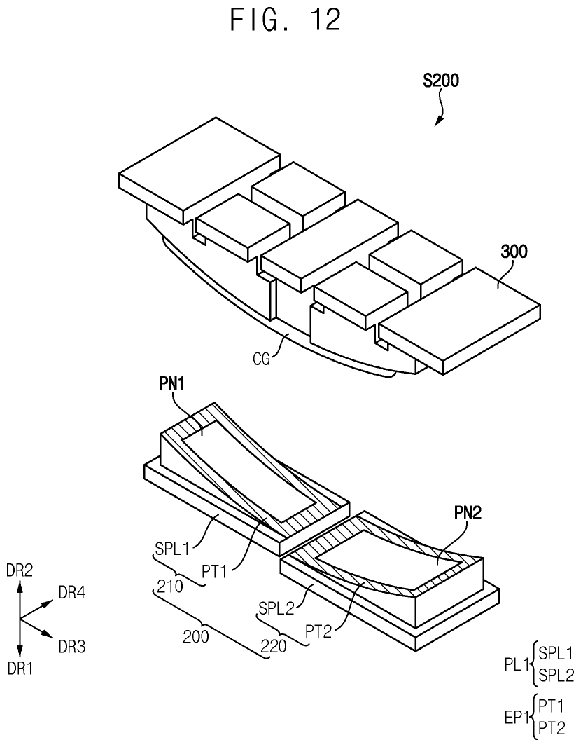

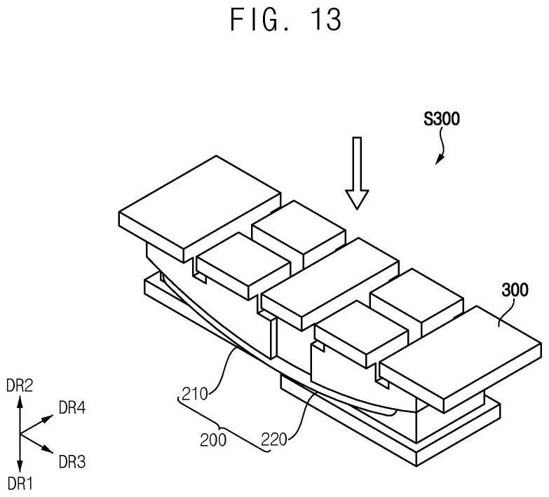

For example, FIG. 7 is a flowchart of a method (S10) of lamination, and FIGS. 8, 9, 10, and 11 illustrate a step (S100) of molding a shape of a display panel PN. FIG. 12 illustrates a step (S200) of adsorbing the display panel PN and a window CG to the electrostatic chuck unit 100, and FIG. 13 illustrates a step (S300) of bonding the display panel PN and the window CG.

For example, the lamination method (S10) described with reference to FIGS. 7, 8, 9, 10, 11, 12, and 13 can be performed using the electrostatic chuck unit 100 and the lamination apparatus 10 described with reference to FIGS. 1, 2, 3, 4, 5, and 6. Hereinafter, repeated descriptions may be omitted or summarized.

Referring to FIGS. 7, 8, 9, 10, and 11, the lamination method (S10) according to an embodiment includes molding the shape of the display panel PN (S100).

The display panel PN is molded by a stage 400 and a bending jig 500. The stage 400 includes a center stage 410, a first side stage 421, a second side stage 422, a first roller 431, and a second roller 432.

The center stage 410 is spaced apart from the first side stage 421 in the third direction DR3, and the second side stage 422 is spaced apart from the center stage 410 in the third direction DR3. For example, the center stage 410 is disposed between the first side stage 421 and the second side stage 422. The first roller 431 is disposed between the first side stage 421 and the center stage 410, and the second roller 432 is disposed between the center stage 410 and the second side stage 422.

In an embodiment, each of the center stage 410, the first side stage 421, and the second side stage 422 is movable in the first direction DR1 or the second direction DR2. The first roller 431 and the second roller 432 are movable in the third direction DR3 or a direction opposite to the third direction DR3.

The bending jig 500 is spaced apart from the stage 400 in the second direction DR2. In an embodiment, the bending jig 500 is convexly curved in the first direction DR1. In addition, the bending jig 500 is movable in the first direction DR1 or the second direction DR2.

Referring to FIG. 8, in an embodiment, the molding of the shape of the display panel PN (S100) includes placing the display panel PN on the stage 400 (S110). For example, the display panel PN is supported by the center stage 410, the first side stage 421, the second side stage 422, the first roller 431, and the second roller 432. The bending jig 500 is spaced apart from the display panel PN in the second direction DR2.

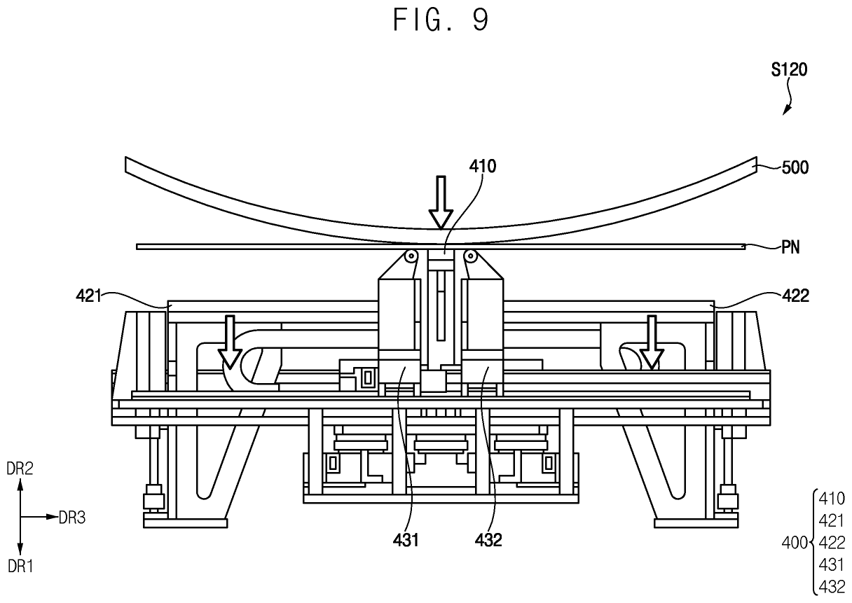

Referring to FIG. 9, in an embodiment, the molding of the shape of the display panel PN (S100) further includes moving each of the first side stage 421, the second side stage 422, and the bending jig 500 in the first direction DR1 (S120).

For example, the display panel PN is supported by the center stage 410, the first roller 431, and the second roller 432, and is in contact with the bending jig 500. The bending jig 500 adsorbs the display panel PN. For example, the bending jig 500 adsorbs a center portion of the display panel PN.

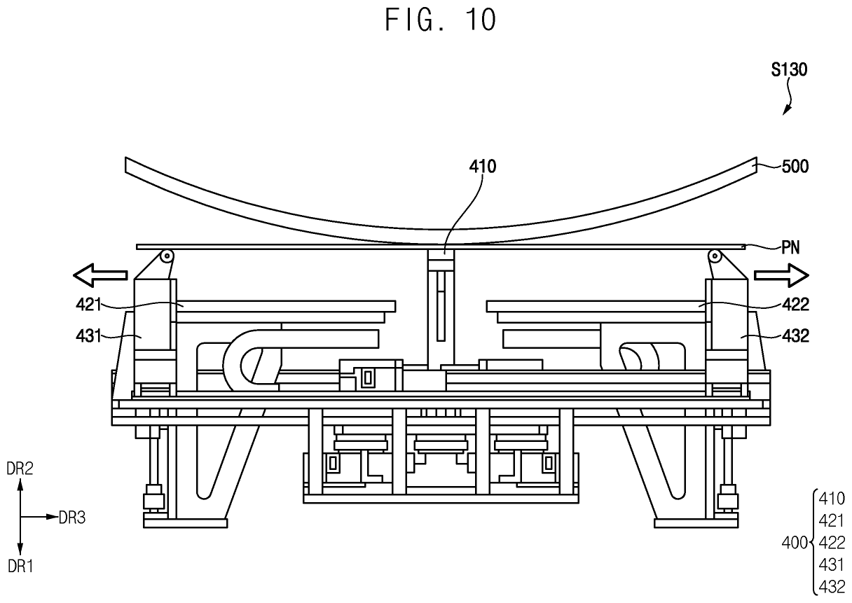

Referring to FIG. 10, in an embodiment, the molding of the shape of the display panel PN (S100) further includes moving the first roller 431 in the direction opposite to the third direction DR3, and moving the second roller 432 in the third direction DR3 (S130).

For example, the center portion of the display panel PN is supported by the center stage 410, and edge portions of the display panel PN are supported by the first roller 431 and the second roller 432.

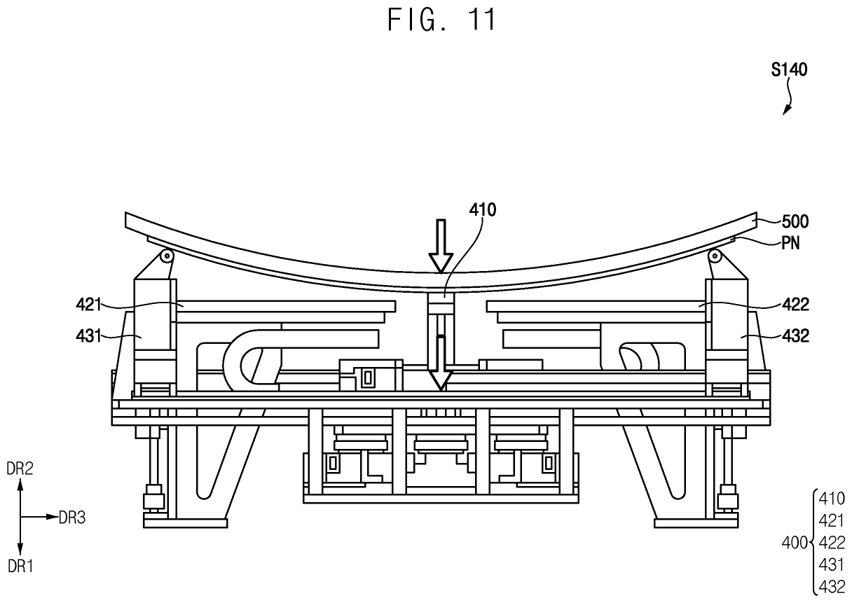

Referring to FIG. 11, in an embodiment, the molding of the shape of the display panel PN (S100) further includes moving each of the center stage 410 and the bending jig 500 in the first direction DR1 (S140). Accordingly, the center portion of the display panel PN, supported by the center stage 410 and in contact with the bending jig 500, is also moved in the first direction DR1.

Since the center portion of the display panel PN is moved in the first direction DR1 and the edge portions of the display panel PN are supported by the first roller 431 and the second roller 432, the shape of the display panel PN is molded to be curved in the first direction DR1. For example, the shape of the display panel PN is formed along a shape of the bending jig 500.

FIG. 11 shows that the center stage 410 and the bending jig 500 are moved to mold the display panel PN, but embodiments of the present disclosure are not necessarily limited thereto. In an embodiment, the first roller 431 and the second roller 432 are movable in the first direction DR1 or the second direction DR2, and as the first roller 431 and the second roller 432 are moved in the second direction DR2, the shape of the display panel PN is molded.

Referring to FIGS. 1, 7, 11, and 12, the lamination method (S10) according to an embodiment further includes adsorbing the display panel PN and the window CG to the first electrostatic chuck 200 and the second electrostatic chuck 300, respectively (S200). The display panel PN includes a first display panel PN1 and a second display panel PN2.

In an embodiment, the first display panel PN1 and the second display panel PN2 have different sizes. For example, the first display panel PN1 is smaller than the second display panel PN2, but embodiments of the present disclosure are not necessarily limited thereto. In an embodiment, the first display panel PN1 and the second display panel PN2 have the same size.

The electrostatic chuck unit 100 includes the first electrostatic chuck 200 and the second electrostatic chuck 300. The first electrostatic chuck 200 includes the first structure 210, which includes the first sub-plate SPL1 and the first pattern PT1, and the second structure 220, which includes the second sub-plate SPL2 and the second pattern PT2.

Each of the first display panel PN1 and the second display panel PN2 molded by the stage 400 and the bending jig 500 are adsorbed to the first electrostatic chuck 200. For example, a voltage is applied to the first electrode pattern EP1, so that the first display panel PN1 is adsorbed to the first structure 210, and the second display panel PN2 is adsorbed to the second structure 220.

For example, a voltage is applied to the first pattern PT1 to generate an electrostatic force between the first pattern PT1 and the first display panel PN1. In addition, a voltage is applied to the second pattern PT2 to generate an electrostatic force between the second pattern PT2 and the second display panel PN2. Accordingly, the first display panel PN1 and the second display panel PN2 are adsorbed to the first structure 210 and the second structure 220, respectively.

The window CG has a shape curved in the first direction DR1. The window CG is adsorbed to the second electrostatic chuck 300. For example, a voltage is applied to the second electrode pattern EP2 to generate an electrostatic force between the second electrode pattern EP2 and the window CG. Accordingly, the window CG is adsorbed to the second electrostatic chuck 300.

Referring to FIGS. 1, 7, 12, and 13, the lamination method (S10) according to an embodiment further includes bonding the first display panel PN1, the second display panel PN2, and the window CG (S300).

The second electrostatic chuck 300 to which the window CG is adsorbed is moved in the first direction DR1 toward the first electrostatic chuck 200 to which the first and second display panels PN1 and PN2 are adsorbed. For example, the second chamber CB2 is moved in the first direction DR1 toward the first chamber CB1. For example, the inside of each of the first chamber CB1 and the second chamber CB2 are in a vacuum state.

Since the second electrostatic chuck 300 is moved in the first direction DR1 toward the first electrostatic chuck 200, the first and second display panels PN1 and PN2 and the window CG are bonded. In an embodiment, the first and second display panels PN1 and PN2 and the window CG are bonded face-to-face in a vacuum state. For example, an upper surface of each of the first and second display panels PN1 and PN2 that faces the window CG and a lower surface of the window CG that faces the first and second display panels PN1 and PN2 are bonded face-to-face as a whole. Accordingly, a display device in which the curved first and second display panels PN1 and PN2 and the curved window CG are bonded can be manufactured.

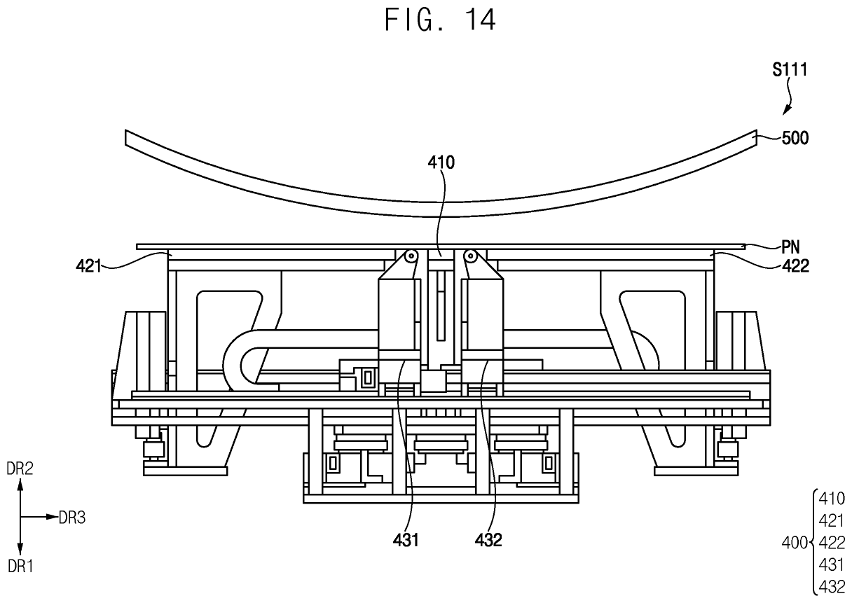

FIGS. 14, 15, 16, and 17 illustrate a lamination method according to an embodiment of the present disclosure.

For example, a lamination method with reference to FIGS. 14, 15, 16, and 17 corresponds to the step (S100) of molding the shape of the display panel PN in the lamination method (S10) described with reference to FIGS. 7, 8, 9, 10, and 11. Hereinafter, repeated descriptions may be omitted or summarized.

Referring to FIGS. 7, 14, 15, 16, and 17, the lamination method (S10) according to an embodiment includes molding the shape of the display panel PN (S100).

Referring to FIG. 14, in an embodiment, the molding of the shape of the display panel PN (S100) includes placing the display panel PN on the stage 400 (S111). For example, the display panel PN is supported by the stage 400. The bending jig 500 is spaced apart from the display panel PN in the second direction DR2.

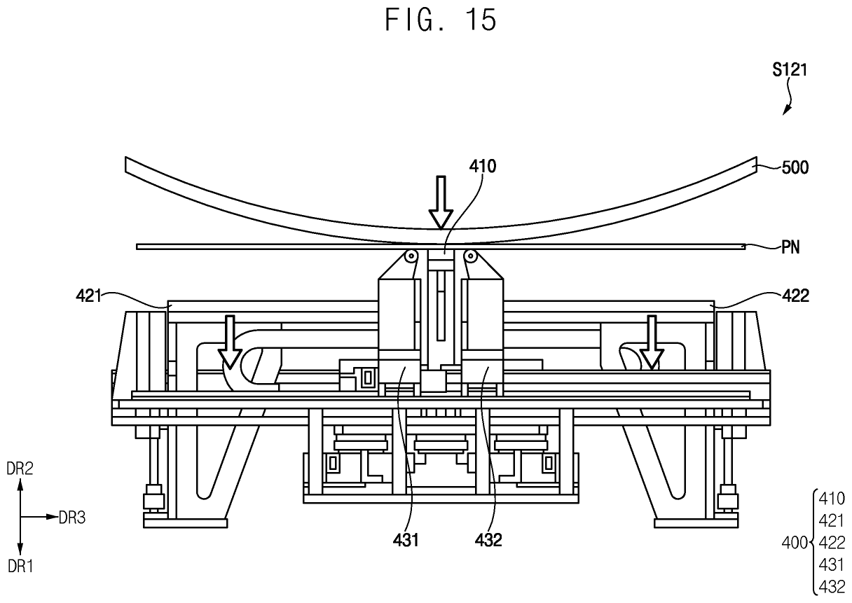

Referring to FIG. 15, in an embodiment, the molding of the shape of the display panel PN (S100) further includes moving each of the first side stage 421, the second side stage 422, and the bending jig 500 in the first direction DR1 (S121).

For example, the display panel PN is supported by the center stage 410, the first roller 431, and the second roller 432, and is in contact with the bending jig 500. The bending jig 500 adsorbs the center portion of the display panel PN.

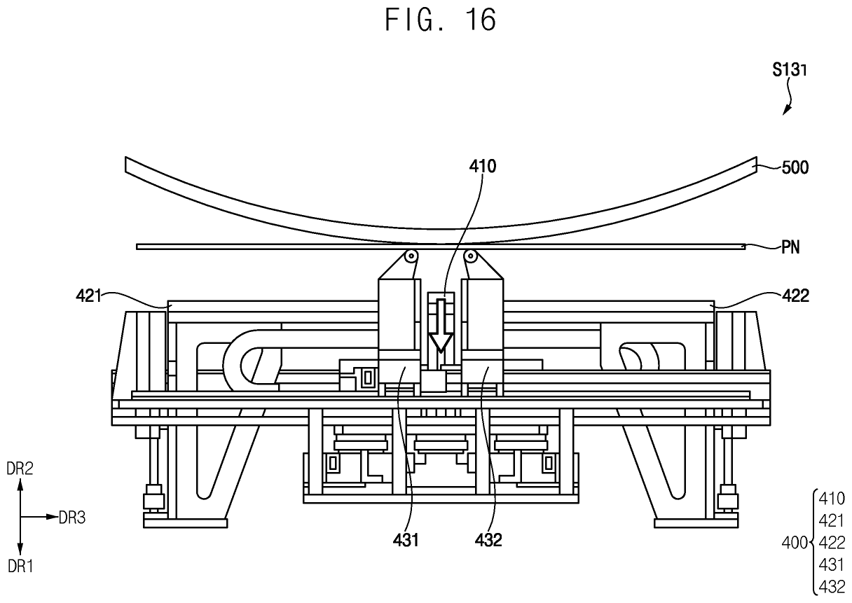

Referring to FIG. 16, in an embodiment, the molding of the shape of the display panel PN (S100) further includes moving the center stage 410 in the first direction DR1 (S131). For example, the center portion of the display panel PN is supported by the first roller 431 and the second roller 432.

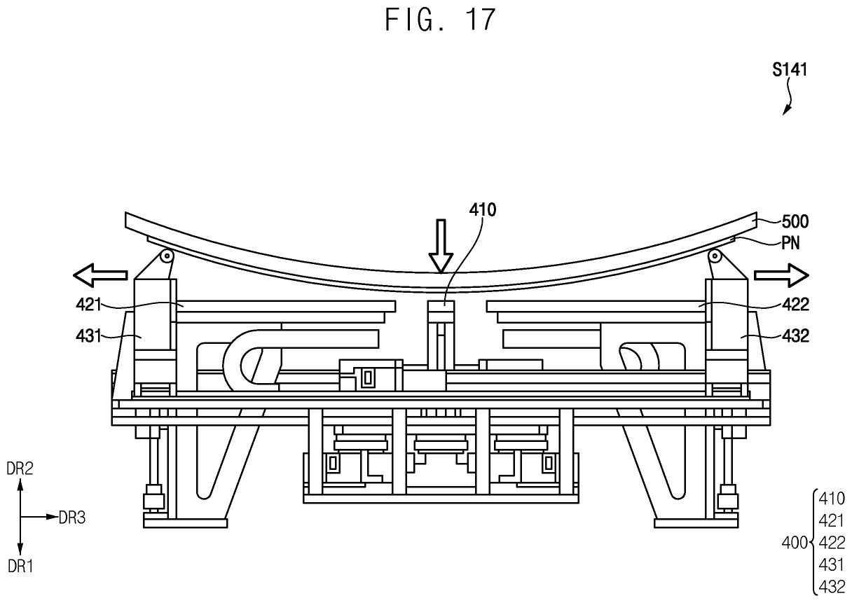

Referring to FIG. 17, in an embodiment, the molding of the shape of the display panel PN (S100) further includes moving the first roller 431 in the direction opposite to the third direction DR3, moving the second roller 432 in the third direction DR3, and moving the bending jig 500 in the first direction DR1 (S141). Accordingly, the center portion of the display panel PN, which is supported by the first roller 431 and the second roller 432 and in contact with the bending jig 500, is also moved in the first direction DR1.

Since the first roller 431 and the second roller 432 are moved from the center portion of the display panel PN to the edge portions of the display panel PN, and the center portion of the display panel PN is moved in the first direction DR1 by the bending jig 500, the shape of the display panel PN is molded to be curved in the first direction DR1. For example, the shape of the display panel PN is formed along the shape of the bending jig 500.

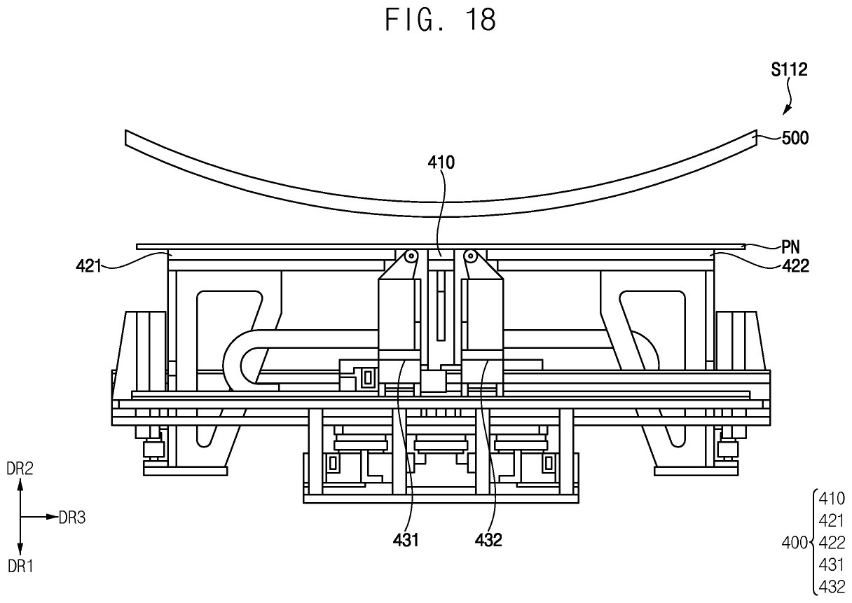

FIGS. 18, 19, 20, and 21 illustrate a lamination method according to an embodiment of the present disclosure.

For example, a lamination method described with reference to FIGS. 18, 19, 20, and 21 correspond to the step (S100) of molding the shape of the display panel PN in the lamination method (S10) described with reference to FIGS. 7, 8, 9, 10, and 11. Hereinafter, repeated descriptions may be omitted or summarized.

Referring to FIGS. 7, 18, 19, 20, and 21, the lamination method (S10) according to an embodiment includes molding the shape of the display panel PN (S100).

Referring to FIG. 18, in an embodiment, the molding of the shape of the display panel PN (S100) includes placing the display panel PN on the stage 400 (S112). For example, the display panel PN is supported by the stage 400. The bending jig 500 is spaced apart from the display panel PN in the second direction DR2.

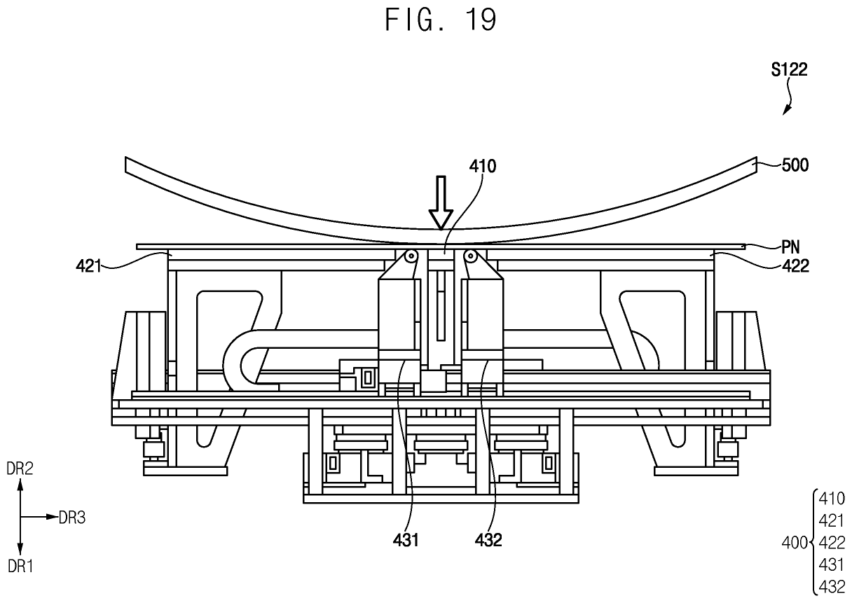

Referring to FIG. 19, in an embodiment, the molding of the shape of the display panel PN (S100) further includes moving the bending jig 500 in the first direction DR1 (S122).

For example, the display panel PN is supported by the center stage 410, the first side stage 421, the second side stage 422, the first roller 431, and the second roller 432, and is in contact with the bending jig 500. The bending jig 500 adsorbs the center portion of the display panel PN.

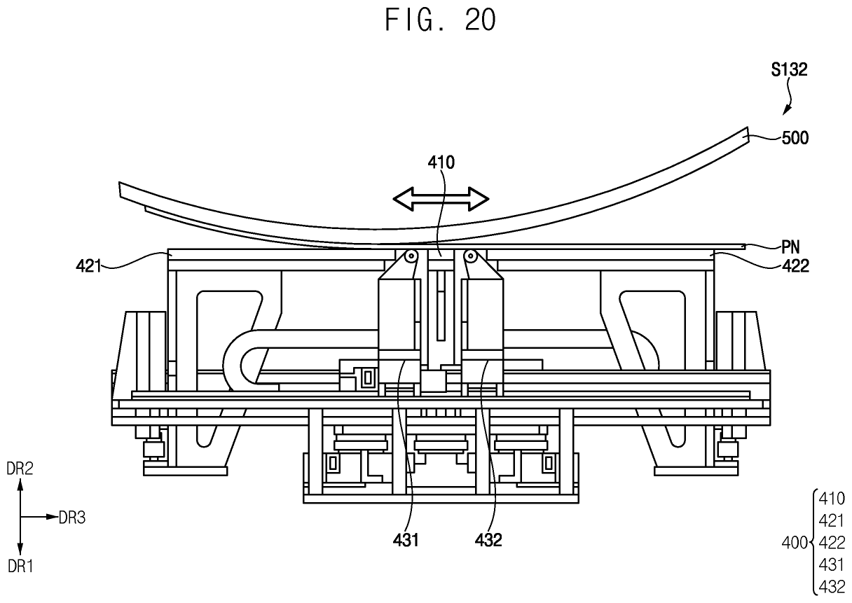

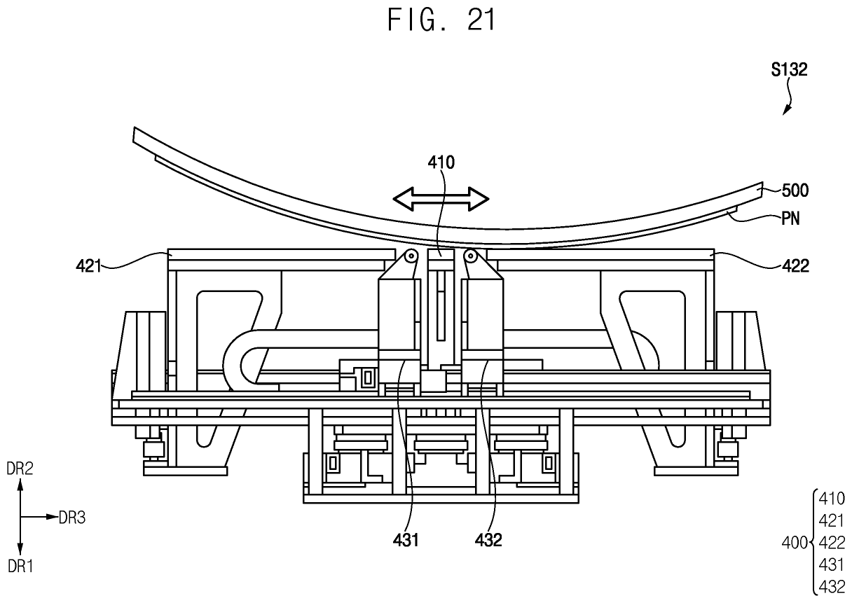

Referring to FIGS. 20 and 21, in an embodiment, the molding of the shape of the display panel PN (S100) further includes rolling the bending jig 500 on the display panel PN (S132). Since the bending jig 500 has a shape that is curved in the first direction DR1, the bending jig 500 can be rolled in the third direction DR3 or the direction opposite to the third direction DR3.

Since the bending jig 500 is rolled in contact with the display panel PN, the shape of the display panel PN is molded to be curved in the first direction DR1. For example, the shape of the display panel PN is formed along the shape of the bending jig 500.

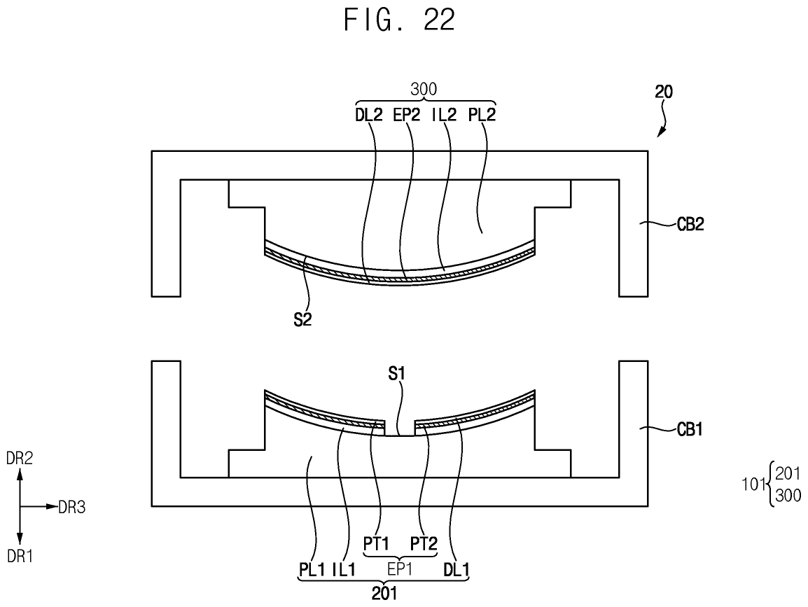

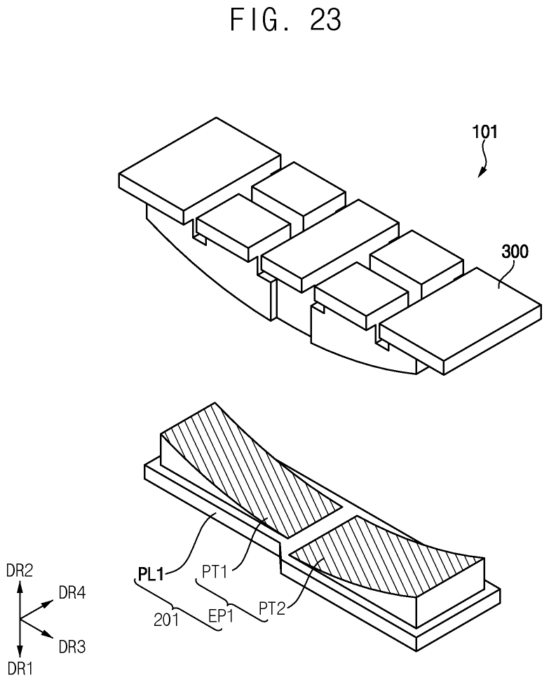

FIG. 22 is a cross-sectional view of a lamination apparatus according to an embodiment of the present disclosure. FIG. 23 is a perspective view of an electrostatic chuck unit in a lamination apparatus of FIG. 22.

A lamination apparatus 20 described with reference to FIGS. 22 and 23 is substantially the same as or similar to the lamination apparatus 10 described with reference to FIGS. 1, 2, 3, 4, 5, and 6, except for a first electrostatic chuck 201. Hereinafter, repeated descriptions may be omitted or summarized.

Referring to FIGS. 22 and 23, in an embodiment, the lamination apparatus 20 includes a first chamber CB1, a second chamber CB2, and an electrostatic chuck unit 101. The electrostatic chuck unit 101 includes the first electrostatic chuck 201 and a second electrostatic chuck 300.

The first chamber CB1 is adjacent to the second chamber CB2 in a first direction DR1. The first electrostatic chuck 201 is disposed in the first chamber CB1, and the second electrostatic chuck 300 is disposed in the second chamber CB2. For example, the second electrostatic chuck 300 is spaced apart from the first electrostatic chuck 201 in a second direction DR2 opposite to the first direction DR1.

The first electrostatic chuck 201 includes a first plate PL1, a first insulating layer IL1, a first electrode pattern EP1, and a first dielectric layer DL1. The first electrode pattern EP1 includes a first pattern PT1 and a second pattern PT2. The first electrostatic chuck 201 can adsorb a first object and a second object.

The first plate PL1 is supported by the first chamber CB1. In an embodiment, a surface S1 of the first plate PL1 adjacent to the second electrostatic chuck 300 is concavely curved in the first direction DR1.

The first insulating layer IL1 is disposed on the surface S1 of the first plate PL1. The first insulating layer IL1 is disposed along a profile of the surface S1 of the first plate PL1. For example, the first insulating layer IL1 is concavely curved in the first direction DR1.

The first electrode pattern EP1 is disposed on the first insulating layer IL1. The first electrode pattern EP1 is disposed along a profile of the first insulating layer IL1. For example, the first electrode pattern EP1 is concavely curved in the first direction DR1.

The first electrode pattern EP1 includes the first pattern PT1 and the second pattern PT2. In an embodiment, the first electrode pattern EP1 and the second electrode pattern EP2 are spaced apart from each other. For example, the second electrode pattern EP2 is spaced apart from the first electrode pattern EP1 in a third direction DR3 that crosses each of the first direction DR1 and the second direction DR2. For example, the third direction DR3 is perpendicular to each of the first direction DR1 and the second direction DR2. However, embodiments of the present disclosure are not necessarily limited thereto, and in other embodiments, the first electrode pattern EP1 and the second electrode pattern EP2 are in contact with each other without being spaced apart from each other.

The first dielectric layer DL1 is disposed on the first electrode pattern EP1. The first dielectric layer DL1 is disposed along a profile of the first electrode pattern EP1. For example, the first dielectric layer DL1 is concavely curved in the first direction DR1. Each of the first object and the second object can be adsorbed on the first dielectric layer DL1.

Accordingly, the first electrostatic chuck 201, which includes the first plate PL1, the first insulating layer IL1, the first electrode pattern EP1, and the first dielectric layer DL1, is supported by the first chamber CB1.

The second electrostatic chuck 300 includes a second plate PL2, a second insulating layer IL2, a second electrode pattern EP2, and a second dielectric layer DL2. The second electrostatic chuck 300 can adsorb a third object.

The second plate PL2 is supported by the second chamber CB2. In an embodiment, a surface S2 of the second plate PL2 adjacent to the first electrostatic chuck 201 is convexly curved in the first direction DR1.

The second insulating layer IL2 is disposed on the surface S2 of the second plate PL2. The second insulating layer IL2 is disposed along a profile of the surface S2 of the second plate PL2. For example, the second insulating layer IL2 is convexly curved in the first direction DR1.

The second electrode pattern EP2 is disposed on the second insulating layer IL2. The second electrode pattern EP2 is disposed along a profile of the second insulating layer IL2. For example, the second electrode pattern EP2 is convexly curved in the first direction DR1.

The second dielectric layer DL2 is disposed on the second electrode pattern EP2. The second dielectric layer DL2 is disposed along a profile of the second electrode pattern EP2. For example, the second dielectric layer DL2 is convexly curved in the first direction DR1. The third object can be adsorbed on the second dielectric layer DL2.

Accordingly, the second electrostatic chuck 300, which includes the second plate PL2, the second insulating layer IL2, the second electrode pattern EP2, and the second dielectric layer DL2, is supported by the second chamber CB2.

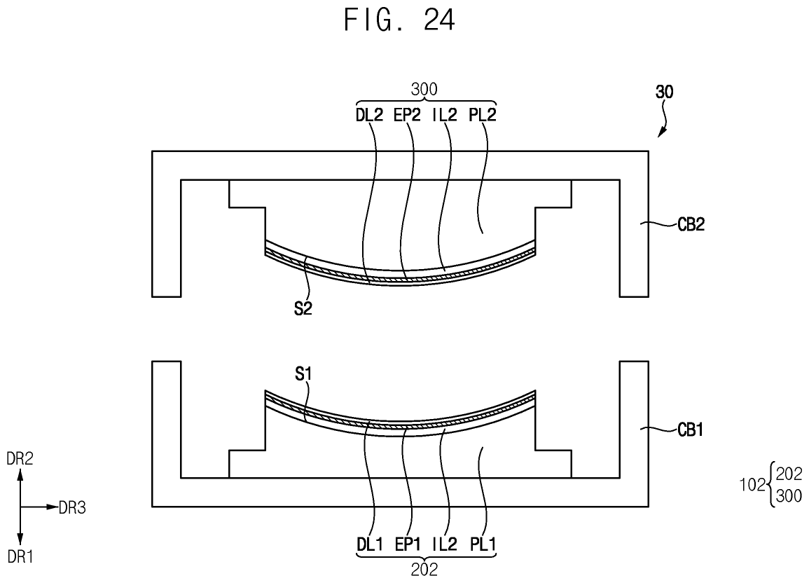

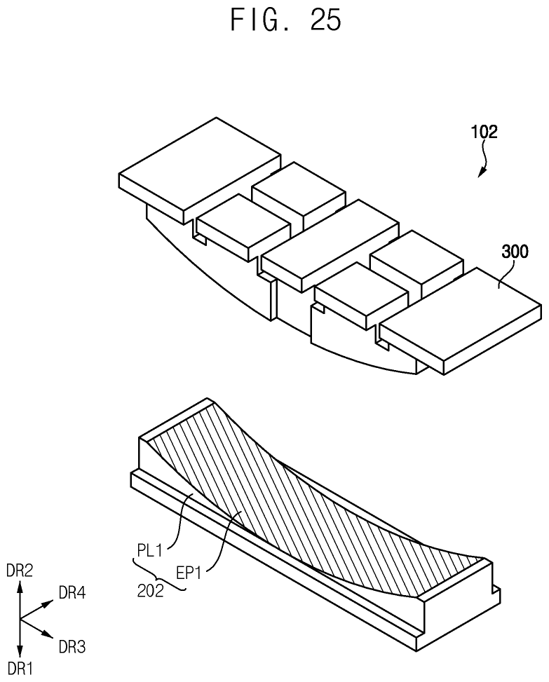

FIG. 24 is a cross-sectional view of a lamination apparatus according to an embodiment of the present disclosure. FIG. 25 is a perspective view of an electrostatic chuck unit in a lamination apparatus of FIG. 24.

A lamination apparatus 30 described with reference to FIGS. 24 and 25 is substantially the same as or similar to the lamination apparatus 10 described with reference to FIGS. 1, 2, 3, 4, 5, and 6, except for a first electrostatic chuck 202. Hereinafter, repeated descriptions may be omitted or summarized.

Referring to FIGS. 24 and 25, in an embodiment, the lamination apparatus 30 includes a first chamber CB1, a second chamber CB2, and an electrostatic chuck unit 102. The electrostatic chuck unit 102 includes the first electrostatic chuck 202 and a second electrostatic chuck 300.

The first chamber CB1 is adjacent to the second chamber CB2 in a first direction DR1. The first electrostatic chuck 202 is disposed in the first chamber CB1, and the second electrostatic chuck 300 is disposed in the second chamber CB2. For example, the second electrostatic chuck 300 is spaced apart from the first electrostatic chuck 202 in a second direction DR2 opposite to the first direction DR1.

The first electrostatic chuck 202 includes a first plate PL1, a first insulating layer IL1, a first electrode pattern EP1, and a first dielectric layer DL1. The first electrostatic chuck 202 can adsorb at least one object.

The first plate PL1 is supported by the first chamber CB1. In an embodiment, a surface S1 of the first plate PL1 adjacent to the second electrostatic chuck 300 is concavely curved in the first direction DR1.

The first insulating layer IL1, the first electrode pattern EP1, and the first dielectric layer DL1 are sequentially disposed on the surface S1 of the first plate PL1. The first insulating layer IL1, the first electrode pattern EP1, and the first dielectric layer DL1 are disposed along a profile of the surface S1 of the first plate PL1. For example, the first insulating layer IL1, the first electrode pattern EP1, and the first dielectric layer DL1 are each concavely curved in the first direction DR1.

Accordingly, the first electrostatic chuck 202, which includes the first plate PL1, the first insulating layer IL1, the first electrode pattern EP1, and the first dielectric layer DL1, is supported by the first chamber CB1.

The second electrostatic chuck 300 includes a second plate PL2, a second insulating layer IL2, a second electrode pattern EP2, and a second dielectric layer DL2. The second electrostatic chuck 300 can adsorb at least one object.

The second plate PL2 is supported by the second chamber CB2. In an embodiment, a surface S2 of the second plate PL2 adjacent to the first electrostatic chuck 202 is convexly curved in the first direction DR1.

The second insulating layer IL2, the second electrode pattern EP2, and the second dielectric layer DL2 are sequentially disposed on the surface S2 of the second plate PL2. The second insulating layer IL2, the second electrode pattern EP2, and the second dielectric layer DL2 are disposed along a profile of the surface S2 of the second plate PL2. For example, the second insulating layer IL2, the second electrode pattern EP2, and the second dielectric layer DL2 are each convexly curved in the first direction DR1.

Accordingly, the second electrostatic chuck 300, which includes the second plate PL2, the second insulating layer IL2, the second electrode pattern EP2, and the second dielectric layer DL2, is supported by the second chamber CB2.

Embodiments of the present disclosure can be incorporated into a manufacturing process of various display devices. For example, an embodiment of the present disclosure can be incorporated into a manufacturing process of various display devices, such as display devices for vehicles, ships and aircraft, portable communication devices, display devices for exhibition or information transmission, medical display devices, etc.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to specific embodiments disclosed, and that modifications to disclosed embodiments, as well as other embodiments, are intended to be included within the scope of the appended claims.

What is claimed is:

1. An electrostatic chuck unit, comprising:
a first electrostatic chuck that includes a first plate that includes a surface that is concavely curved in a first direction and a first electrode pattern disposed on the surface of the first plate; and
a second electrostatic chuck spaced apart from the first electrostatic chuck in a second direction opposite to the first direction, and that includes a second plate that includes a surface adjacent to the first electrostatic chuck and that is convexly curved in the first direction and a second electrode pattern disposed on the surface of the second plate,
wherein each of the first electrode pattern and the second electrode pattern includes an electrode, and
a width of the electrode is between 10 mm and 30 mm.

2. The electrostatic chuck unit of claim 1, wherein
the first electrostatic chuck further includes a first dielectric layer disposed on the first electrode pattern,
the second electrostatic chuck further includes a second dielectric layer disposed on the second electrode pattern, and
a thickness of each of the first dielectric layer and the second dielectric layer is between 0.05 mm and 0.075 mm.

3. The electrostatic chuck unit of claim 1, wherein a distance between the electrode of each of the first electrode pattern and the second electrode pattern is between 0.5 mm and 2.0 mm.

4. The electrostatic chuck unit of claim 1, wherein the first electrode pattern includes:
a first pattern; and
a second pattern that has a size that differs from a size of the first pattern.

5. The electrostatic chuck unit of claim 4, wherein the first pattern and the second pattern are spaced apart from each other.

6. The electrostatic chuck unit of claim 4, wherein the first plate includes:
a first sub-plate disposed below the first pattern; and
a second sub-plate disposed below the second pattern.

7. The electrostatic chuck unit of claim 6, wherein the first sub-plate and the second sub-plate are spaced apart from each other.

8. The electrostatic chuck unit of claim 1, wherein
each of the first electrode pattern and the second electrode pattern includes:
a first area;
a second area spaced apart from the first area in a third direction that crosses each of the first direction and the second direction; and
a third area located between the first area and the second area, and
each of a first width of an electrode in the first area and a second width of an electrode in the second area is less than a third width of an electrode in the third area.

9. The electrostatic chuck unit of claim 8, wherein each of a first distance between electrodes in the first area and a second distance between electrodes in the second area is less than a third distance between electrodes in the third area.

10. The electrostatic chuck unit of claim 1, wherein each of the first electrode pattern and the second electrode pattern includes vacuum holes arranged along a third direction that crosses each of the first direction and the second direction and a fourth direction that crosses each of the first direction, the second direction, and the third direction.

11. The electrostatic chuck unit of claim 1, wherein each of the first electrode pattern and the second electrode pattern includes an alignment mark.

12. The electrostatic chuck unit of claim 1, wherein each of the first electrode pattern and the second electrode pattern includes:
a first electrode; and
a second electrode charged with a polarity that differs from a polarity of the first electrode.

13. A lamination apparatus comprising:
a first chamber;
a second chamber adjacent to the first chamber in a first direction;
a first electrostatic chuck disposed in the first chamber; and
a second electrostatic chuck disposed in the second chamber,
wherein the first electrostatic chuck includes:
a first plate that includes a surface that is concavely curved in a second direction opposite to the first direction; and
a first electrode pattern disposed on the surface of the first plate;
wherein the second electrostatic chuck includes:
a second plate that includes a surface adjacent to the first electrostatic chuck and that is convexly curved in the second direction; and
a second electrode pattern disposed on the surface of the second plate,
wherein each of the first electrode pattern and the second electrode pattern includes an electrode, and
a width of the electrode is between 10 mm and 30 mm.

14. The lamination apparatus of claim 13, wherein
the first electrostatic chuck further includes a first dielectric layer disposed on the first electrode pattern,
the second electrostatic chuck further includes a second dielectric layer disposed on the second electrode pattern, and
a thickness of each of the first dielectric layer and the second dielectric layer is between 0.05 mm and 0.075 mm.

15. The lamination apparatus of claim 13, wherein a distance between an electrode of each of the first electrode pattern and the second electrode pattern is between 0.5 mm and 2.0 mm.

16. The lamination apparatus of claim 13, wherein the first electrode pattern includes:
a first pattern; and
a second pattern that has a size that differs from a size of the first pattern.

17. The lamination apparatus of claim 16, wherein the first pattern and the second pattern are spaced apart from each other.

18. The lamination apparatus of claim 16, wherein the first plate includes:
a first sub-plate disposed below the first pattern; and
a second sub-plate disposed below the second pattern.

19. The lamination apparatus of claim 18, wherein the first sub-plate and the second sub-plate are spaced apart from each other.

20. The lamination apparatus of claim 13, wherein
each of the first electrode pattern and the second electrode pattern includes:
a first area;
a second area spaced apart from the first area in a third direction that crosses each of the first direction and the second direction; and
a third area located between the first area and the second area, and
each of a first width of an electrode in the first area and a second width of an electrode in the second area is less than a third width of an electrode in the third area.

21. The lamination apparatus of claim 20, wherein each of a first distance between electrodes in the first area and a second distance between electrodes in the second area is less than a third distance between electrodes in the third area.

22. The lamination apparatus of claim 21, wherein each of the first electrode pattern and the second electrode pattern includes a vacuum hole arranged along a third direction that crosses each of the first direction and the second direction and a fourth direction that crosses each of the first direction, the second direction, and the third direction.

23. A method of lamination, the method comprising:
molding a shape of a display panel;
adsorbing the display panel to a surface of a first electrostatic chuck;
adsorbing a window to a surface of a second electrostatic chuck adjacent to the first electrostatic chuck, wherein the second electrostatic chuck is spaced apart from the first electrostatic chuck in a first direction; and
bonding the display panel and the window by using the first electrostatic chuck and the second electrostatic chuck.

24. The method of claim 23, wherein the molding of the shape of the display panel includes molding
the display panel to be curved in a second direction opposite to the first direction.

25. The method of claim 23, wherein the molding of the shape of the display panel includes molding
the display panel by using a stage and a bending jig spaced from the stage in the first direction and that is curved in a second direction opposite to the first direction.

26. The method of claim 25, wherein the stage includes:
a first side stage;
a center stage spaced apart from the first side stage in a third direction that crosses each of the first direction and the second direction;
a second side stage spaced apart from the center stage in the third direction;
a first roller disposed between the first side stage and the center stage; and
a second roller disposed between the center stage and the second side stage.

27. The method of claim 26, wherein the molding of the shape of the display panel includes:
placing the display panel on the stage;
moving the first side stage, the second side stage, and the bending jig in the second direction and contacting the bending jig and the display panel;
moving the first roller in a fourth direction opposite to the third direction and moving the second roller in the third direction; and
moving the bending jig in the second direction so that the display panel is molded.

28. The method of claim 26, wherein the molding of the shape of the display panel includes:
placing the display panel on the stage;
moving the first side stage, the second side stage, and the bending jig in the second direction and contacting the bending jig and the display panel;
moving the center stage in the second direction; and
moving the first roller in a fourth direction opposite to the third direction, moving the second roller in the third direction, and moving the bending jig in the second direction so that the display panel is molded.

29. The method of claim 26, wherein the molding of the shape of the display panel includes:
placing the display panel on the stage;
moving the bending jig in the second direction and contacting the bending jig and the display panel; and
rolling the bending jig in the third direction and in a fourth direction opposite to the third direction so that the display panel is molded.

30. The method of claim 23, wherein
the surface of the first electrostatic chuck is concavely curved in a second direction opposite to the first direction, and
the surface of the second electrostatic chuck is convexly curved in the second direction.
